(19) United States
(12) Patent Application Publication
(10) Pub. No.: US 2014/0124775 A1
(43) Pub. Date: May 8, 2014

(54) COATING SOLUTION FOR FORMING TRANSPARENT DIELECTRIC THIN FILM FOR LOW-TEMPERATURE SOLUTION PROCESS AND TRANSPARENT INORGANIC THIN-FILM TRANSISTOR HAVING THIN FILM FORMED BY THE COATING SOLUTION

(71) Applicant: Industry-Academic Cooperation Foundation, Yonsei University, Seoul (KR)

(72) Inventors: Joo Ho Moon, Seoul (KR); Woo Seok Yang, Seoul (KR); Keun Kyu Song, Yogin-si (KR); Yang Ho Jung, Seoul (KR)

(73) Assignee: Industry-Academic Cooperation Foundation, Yonsei University, Seoul (KR)

(21) Appl. No.: 14/016,324

(22) Filed: Sep. 3, 2013

(30) Foreign Application Priority Data
Nov. 8, 2012 (KR) 10-2012-125890

(51) Int. Cl. H01L 29/786

(52) U.S. Cl. CPC H01L 29/78603
USPC 257/43; 106/287.17; 427/58; 427/126.1

(57) ABSTRACT

A coating solution coating solution for forming a transparent dielectric thin film is provided. The coating solution includes a precursor for a first substance including aluminum, a precursor for a second substance including zirconium, and a solvent that dissolves the first and second substances. The solvent is composed of a first solvent and a second solvent.

### CROSS REFERENCE TO RELATED APPLICATION

The present application claims priority from Korean Patent Application Number 10-2012-0125890 filed on Nov. 8, 2012, the entire contents of which are incorporated herein for all purposes by this reference.

### BACKGROUND OF THE INVENTION

1. Field of the Invention

This invention relates to manufacture of a transparent thin film, and more particularly, to a coating solution for manufacturing a thin film at low temperature by a solution process and a transparent thin-film transistor including a thin film that is manufactured using the same coating solution.

2. Description of Related Art

In response to the increasing demand and interest about thin-film displays, such as liquid crystal displays (LCDs) and organic light-emitting diodes (OLEDs), researches for a next-generation flexible display which can be used without property degradation when the display is bent or warped are recently in progress.

A thin film transistor, a basic unit device that functions as a switch, is a core component of all information and electronic devices and displays, and semiconductor and dielectric are core parts of the thin film transistor.

At present, polycrystalline silicon that is widely used as a semiconductor material has an advantage in the aspect of property, durability, performance and stability. However, vacuum deposition, laser annealing processes and the like are required so as to form a thin film. As a result, the manufacturing cost is high and the equipment for performing such a process is also expensive, thereby increasing display production cost.

Inorganic zinc oxide (ZnO) that is considered as a new thin-film transistor material is receiving plenty of attention regarding its use for a channel layer of an active area in the thin-film transistor since it has a wide energy band gap and superior light transmittance. In addition, in order to obtain better performance by controlling the carrier density and the like in inorganic zinc oxide, studies on various zinc oxide-type semiconductor layers, such as InZnO and ZnSnO layers, are in progress.

Meanwhile, as typical dielectric materials, silicon dioxide (SiO₂) and silicon nitride (SiNx) showing superior stability are used. However, these materials have problems in that they require expensive vacuum equipment and have a relatively low dielectric constant. Accordingly, low power operation is impossible, and the low power operation condition required for mobile displays and the like cannot be satisfied.

Many inorganic dielectrics having a high dielectric constant, such as ZrO₂, Al₂O₃, HfO₂, TiO₂ and Y₂O₃, are researched and reported as a dielectric that can replace silicon dioxide (SiO₂) and silicon nitride (SiNx) (e.g., Korean Patent No. 10-718839). These materials having a high dielectric constant are watched due to advantages such as low power operation, high mobility and high transmittance. However, expensive vacuum equipment or heat treatment at high temperature (>400° C.) are essentially required in order to produce a high-quality inorganic dielectric thin film. In addition, when heat treatment is performed at high temperature, it is impossible to fabricate a device such as a transistor on a flexible substrate, which is problematic.

Solution processes, such as spin coating, dip coating, drop casting and ink-jet printing, are being actively researched due to their advantages of production cost saving, mass production and large area processing. However, in the case of manufacturing a dielectric thin film based on the solution process, high temperature heat treatment is required as stated above. In contrast, heat treatment at low temperature (<300° C.) has problems in that a leakage current value is relatively high and a flat film cannot be made.

In the case of an organic based dielectric or organic-inorganic hybrid dielectric, it is possible to form a dielectric thin film at low temperature (<300° C.). However, since chemical/thermal stability is greatly reduced, it is difficult to apply the organic based dielectric or organic-inorganic hybrid dielectric to a real process. In addition, the organic based dielectric or organic-inorganic hybrid dielectric has relatively low mobility when combined with inorganic semiconductor such as ZnO, IZO or ZTO.

### BRIEF SUMMARY OF THE INVENTION

Various aspects of the present invention provide a method of manufacturing an inorganic dielectric thin film that shows superior insulation performance even at low temperature by a solution process (e.g., at 300° C. or below, preferably, at 250° C. or below), a coating solution to be used in the same method, and a flexible high-performance transparent thin-film transistor that can be applied to a flexible substrate or a transparent substrate by using the dielectric thin film.

In an aspect of the present invention, provided is a coating solution for forming a transparent dielectric thin film. The coating solution includes a precursor for a first substance including aluminum, a precursor for a second substance including zirconium and a solvent that dissolves the first and second substances. The solvent is composed of a first solvent and a second solvent.

According to an exemplary embodiment of the present invention, in the coating solution, the precursor for the first substance may be one selected from among aluminum nitride, aluminum chloride and aluminum acetate, and the precursor for the second substance may be one selected from among zirconium nitride, zirconium chloride and zirconium acetate.

In the coating solution, the precursor for the first substance and the precursor for the second substance may be mixed at a ratio ranging from 97:3 to 50:50.

In the coating solution, the first and second solvents may be two solvents selected from among acetonitrile, ethylene glycol, 2-methoxy ethanol, ammonia solution, acetic acid and isopropyl alcohol.

In the coating solution, the first solvent and the second solvent may be mixed at a ratio ranging from 30:70 to 70:30.

In another aspect of the present invention, provided is a method of manufacturing a transparent dielectric thin film. The method includes the following steps of: preparing a coating solution by dissolving a precursor for a first substance and a precursor for a second substance into a solvent in which two solvents are mixed, forming a thin film on a substrate by applying the coating solution on the substrate through a solution process, and heat-treating the thin film formed on the substrate at a temperature of 300° C. or below.

According to an exemplary embodiment of the present invention, in the method of manufacturing a transparent dielectric thin film, the precursor for the first substance may be one selected from among aluminum nitride, aluminum chloride and aluminum acetate, and the precursor for the second substance may be one selected from among zirconium nitride, zirconium chloride and zirconium acetate.

In the manufacturing method, the first and second solvents may be two solvents selected from among acetonitrile, ethylene glycol, 2-methoxy ethanol, ammonia solution, acetic acid and isopropyl alcohol.

In the manufacturing method, the heat-treating step may be performed at a temperature of about 250° C.

In a further aspect of the present invention, provided is a transparent inorganic thin-film transistor. The transparent inorganic thin-film transistor includes a dielectric thin film that is formed using a coating solution that is formed by dissolving a precursor for a first substance selected from among aluminum nitride, aluminum chloride and aluminum acetate and a precursor for a second substance selected from among zirconium nitride, zirconium chloride and zirconium acetate into a solvent in which two solvents selected from among acetonitrile, ethylene glycol, 2-methoxy ethanol, ammonia solution, acetic acid and isopropyl alcohol are mixed.

According to an exemplary embodiment of the present invention, in the transistor, the dielectric thin film is formed by heat treatment at a temperature of 300° C. or below.

When the thin film is formed using the coating solution according to the present invention, it is possible to realize high insulation performance even though the thin film is formed by low temperature heat treatment. It is therefore possible to manufacture a thin-film transistor on a flexible substrate using a low-price solution process and to reduce manufacturing cost.

### BRIEF DESCRIPTION OF THE DRAWINGS

FIG. 1 is graphs showing that a thin film formed by adding zirconium oxide to aluminum oxide according to the present invention exhibits superior insulation performance even at low temperature;

FIG. 2 is graphs showing X-ray photoelectron spectroscopy (XPS) in which insulation performance is improved due to formation of a larger amount of oxide at low temperature and reduced defect sites (hydroxyl+lattice defects) when zirconium is added;

FIG. 3 is a view showing the flatness of a thin film formed according to the present invention;

FIG. 4 is a view showing the transmittance of a thin-film transistors including a thin film of the related art and the transmittance of a thin-film transistors including a thin film formed according to the present invention; and

FIG. 5 are graphs showing transmittance properties of a thin-film transistor including a thin film formed according to the present invention.

### DETAILED DESCRIPTION OF THE INVENTION

Reference will now be made in detail to various embodiments of the present invention with reference to the accompanying drawings. In the following description of the present invention, detailed descriptions of well-known technologies will be omitted. For instance, while a thin-film transistor was manufactured using a related-art technique in order to examine its properties, descriptions of such manufacture of the thin-film transistor will be omitted. Although these descriptions are omitted, a person having ordinary skill in the art will easily understand the characteristic constitutions and effects of the present invention from the following Description of the Invention.

The inventors have carried out researches on a material that can make a dielectric thin film having superior insulation performance even at low temperature by a solution process, and consequently completed the present invention.

That is, the present invention provides a technology of manufacturing a dielectric thin film that can be manufactured at low temperature by using a solution process and a high-performance transparent inorganic thin-film transistor that is manufactured by this technique. Specifically, a dielectric thin film that has superior dielectric property even at low temperature, for instance, at 300° C. or below, preferably at about 250° C. is provided using a mixture of aluminum oxide and zirconium oxide. It is possible to manufacture a high-performance thin-film transistor on a flexible plastic substrate of, for example, polyimide, using the dielectric thin film. Accordingly, flexible displays, such as plastic thin-film transistor liquid-crystal displays (TFT-LCDs) and electric papers, and flexible electronic devices, such as radio frequency identification devices (RFIDs) and smart cards, can be implemented.

In the present invention, the reason why superior dielectric property is obtained at low temperature is that a greater amount of oxide is formed even at low temperature when zirconium component is added, and that the amount of a hydroxyl group and oxygen holes which can be a current channel is reduced. This was analyzed by X-ray photoelectron spectroscopy (XPS).

In addition, a thin-film transistor that has superior performance, such as superior transmittance and high mobility, was manufactured by combining a variety of substrates, such as a P+ type silicon wafer, a glass and a plastic substrate, with a semiconductor thin film (InZnO, ZnO) produced via aquatic or non-aquatic processing using the manufactured dielectric thin film.

Reference will now be made in greater detail to the present invention, examples of which are illustrated in the accompanying drawings.

According to the present invention, an inorganic dielectric thin film in which zirconium oxide is added to aluminum oxide is provided. This is formed using a coating solution for forming a transparent dielectric thin film. The coating solution includes a first substance (precursor) including aluminum, a second substance (precursor) including zirconium, and a solvent that dissolves the first and the second substances, the solvent being composed of a first solvent and a second solvent.

Regarding the properties of aluminum oxide (Al₂O₃), the dielectric constant is inferior (that is, this property is not good) and the breakdown voltage is low (that is, this property is good). Zirconium oxide has opposite properties. The inventors of the present invention discovered that it is possible to manufacture a thin film that has superior insulation performance even at low temperature when the coating solution is produced by mixing the two substances that have opposite properties, and consequently completed the present invention.

According to the present invention, one selected from among aluminum nitride, aluminum chloride (e.g. AlCl₃) and aluminum acetate can be used as the first substance, and one selected from among zirconium nitride, zirconium chloride (ZrCl₄) and zirconium acetate can be used as the second substance. In the present invention, the first substance and the second substance are mixed at a ratio ranging from 97:3 to 50:50, preferably, 90:10. That is, according to the experiments that the inventors repeatedly carried out, the performance of the dielectric thin film varies according to the mixing ratio of the first substance and the second substance. Accordingly, the inventors selected the above ratio by optimizing the mixing ratio of the first and the second substances in the aspect of dielectric constant and insulation level at each temperature.

The solvent can be produced by selecting two solvents, i.e. the first and the second solvents, from among acetonitrile, ethylene glycol, 2-methoxy ethanol, ammonia solution, acetic acid and isopropyl alcohol. Meanwhile, according to an embodiment of the invention, the first solvent and the second solvent are mixed at a ratio ranging from 30:70 to 70:30. Like the mixing ratio of the first and the second substances, the inventors observed that the properties change according to the mixing ratio of the first and second solvents, and found out that the ratio above is optimum in the aspect of the solubility of the precursor and the coating performance of the coating solution. In particular, it is preferred that the first and the second solvents be mixed at a ratio of 35:65.

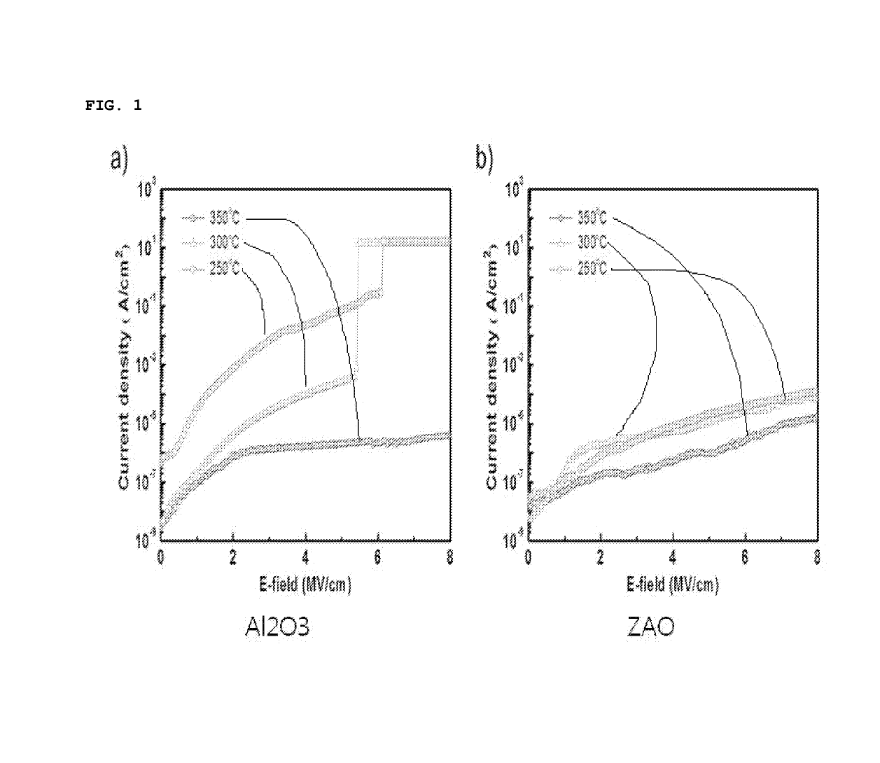

The inventors manufactured the inorganic dielectric thin film in which zirconium oxide is added to aluminum oxide by performing a solution process, for example a spin coating processing using the solution mixture of the first substance, the second substance and the solvent to thus form a thin film, followed by heat treatment (the precursor is converted into an oxide form when the spin coating and the heat treatment are performed after the first and the second substances are dissolved into the solvent). The properties were analyzed, and the results are presented in FIG. 1 to FIG. 3.

FIG. 1 shows the current density after heat treatment at low temperature, that is, at 250° C. in manufacture of the thin film. When compared to the comparative example (Al₂O₃ thin film) on the left, it is noticeable that the current density of the thin film (ZAO thin film) according to the present invention is largely reduced by low temperature heat treatment. This means superior insulation performance is realized even by the heat treatment at relatively low temperature of 250° C.

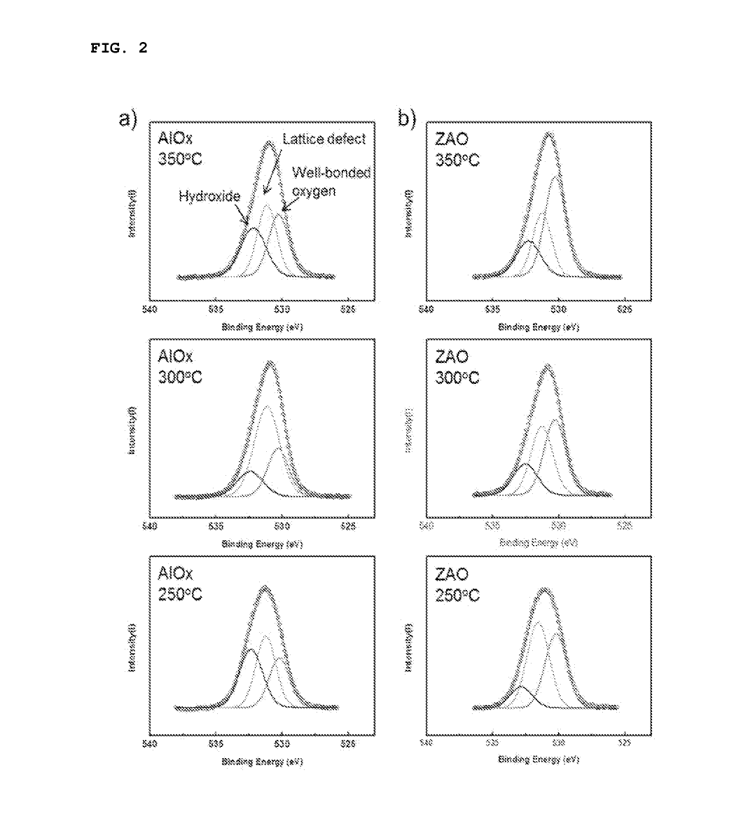

As above, regarding the reason of superior insulation performance realized even by relatively low temperature heat treatment, the inventors analyzed each thin film using X-ray photoelectron spectroscopy (XPS), and the results are presented in FIG. 2.

As shown in FIG. 2, a total amount of hydroxyl group and oxygen holes which can be a current channel in the thin film according to the present invention is reduced, and the amount of oxide formed at low temperature is larger than expected. It seems that superior dielectric properties are realized even at relatively low temperature.

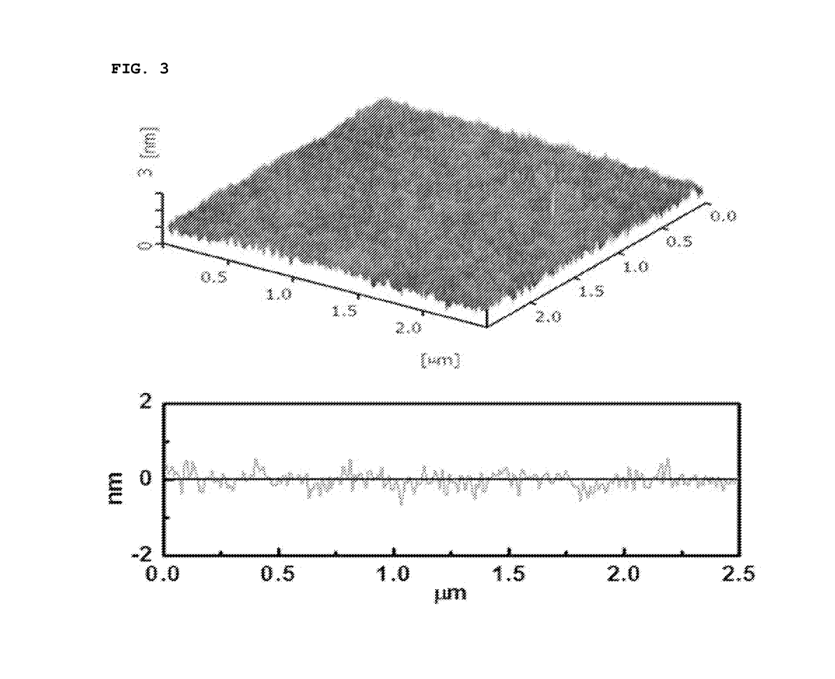

In addition, the inventors measured the flatness of the dielectric thin film formed as above, and presented the results in FIG. 3. As shown in FIG. 3, the average flatness (RMS) is about 0.22 nm. This value is left behind the values that were reported in the related art.

Also, the inventors manufactured a thin-film transistor using the dielectric thin film and the solution that were manufactured as above, and measured their transmittance and mobility.

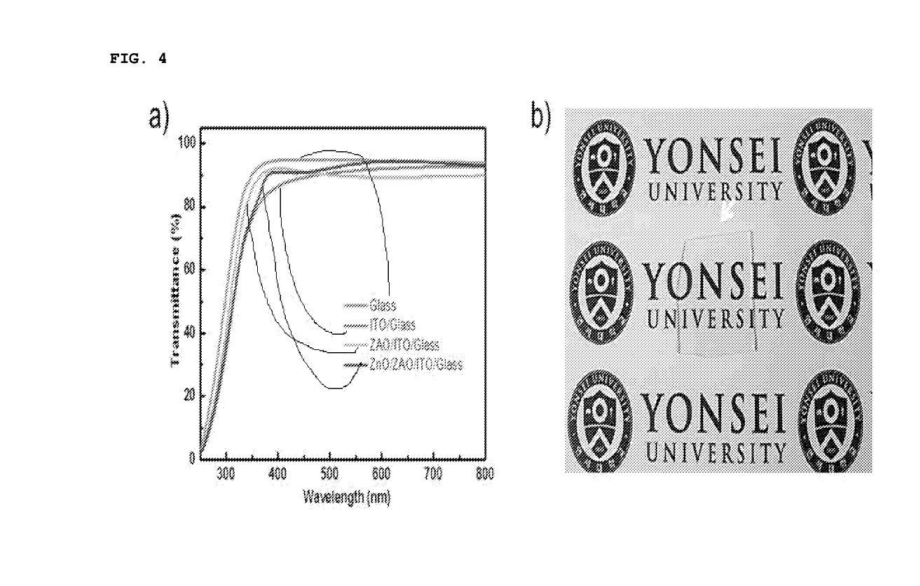

First, referring to FIG. 4 that shows transmittance measurement results according to the wavelength, all of devices exhibited a high transmittance of 90% or more.

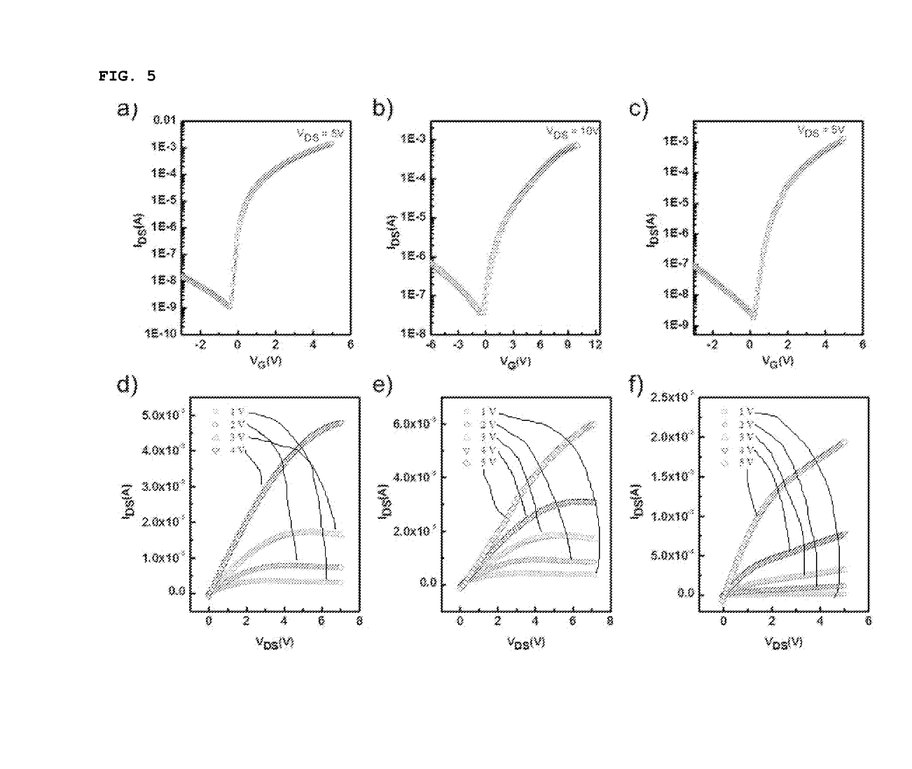

Meanwhile, as noticeable in FIG. 5 that shows the transmission properties of thin-film transistors, high mobility values are obtained at a low voltage (5V). Specifically, processing condition, mobility (μ), on/off ratio, subthreshold swing(s), interfacial trap density, and the like are presented in Table 1. When IZO and ZnO semiconductors are heat-treated at 350° C., they have large mobility values of 53 and 48.9 and a large on/off ratio of about 10⁶. A low temperature IZO device that is heat-treated at 250° C. also exhibits a relatively large mobility value of about 12. They can be regarded very high values considering that the mobility of an a-Si based device that is commercially available and commonly used is about 1.

TABLE 1

| | | | | | | | Interfacial |
|---|---|---|---|---|---|---|---|
| | | | | | | | trap |
| Substrate/ | Semiconductor | Tₐ* | μₛₐₜ | | Vₜₕ | S | density |
| gate | type | (° C.) | (cm²V⁻¹s⁻¹) | On/off | (V) | (V/decade) | (cm⁻²eV⁻¹) |
| p⁺⁺ Si | IZO | 350 | 53 | 1.26 × 10⁶ | 1.07 | 0.12 | 6.55 × 10¹¹ |
| (a), (d) | | | | | | | |
| p⁺⁺ Si | IZO | 250 | 12 | 1.9 × 10⁴ | 2.46 | 0.71 | 4.79 × 10¹² |
| (b), (e) | | | | | | | |
| p⁺⁺ Si | ZnO | 350 | 48.9 | 7.52 × 10⁵ | 1.42 | 0.25 | 2.02 × 10¹² |
| (c), (f) | | | | | | | |

(Tₐ*: annealing temperature)

Although the present invention has been described hereinabove with respect to the exemplary embodiments, it should be understood that the present invention is not limited to the foregoing embodiments. It should be understood that the foregoing embodiments can be made into various alterations and modifications without departing from the scope of the appended claims, and all such alterations and modifications fall within the scope of the present invention. Therefore, the present invention shall be defined by only the claims and their equivalents.

1. A coating solution coating solution for forming a transparent dielectric thin film, the coating solution comprising:
a precursor for a first substance including aluminum;
a precursor for a second substance including zirconium, and
a solvent that dissolves the first and second substances,
wherein the solvent is composed of a first solvent and a second solvent.

2. The coating solution according to claim 1, wherein the precursor for the first substance is one selected from among aluminum nitride, aluminum chloride and aluminum acetate, and the precursor for the second substance is one selected from among zirconium nitride, zirconium chloride and zirconium acetate.

3. The coating solution according to claim 2, wherein the precursor for the first substance and the precursor for the second substance are mixed at a ratio ranging from 97:3 to 50:50.

4. The coating solution according to claim 2, wherein the first and second solvents are two solvents selected from among acetonitrile, ethylene glycol, 2-methoxy ethanol, ammonia solution, acetic acid and isopropyl alcohol.

5. The coating solution according to claim 4, wherein the first solvent and the second solvent are mixed at a ratio ranging from 30:70 to 70:30.

6. A method of manufacturing a transparent dielectric thin film, the method comprising the steps of:
preparing a coating solution by dissolving a precursor for a first substance and a precursor for a second substance into a solvent in which two solvents are mixed;
forming a thin film on a substrate by applying the coating solution on the substrate through a solution process, and
heat-treating the thin film formed on the substrate at a temperature of 300° C. or below.

7. The method according to claim 6, wherein the precursor for the first substance is one selected from among aluminum nitride, aluminum chloride and aluminum acetate, and the precursor for the second substance is one selected from among zirconium nitride, zirconium chloride and zirconium acetate.

8. The method according to claim 7, wherein the first and second solvents are two solvents selected from among acetonitrile, ethylene glycol, 2-methoxy ethanol, ammonia solution, acetic acid and isopropyl alcohol.

9. The method according to claim 6, wherein the heat-treating step is performed at a temperature of about 250° C.

10. A transparent inorganic thin-film transistor comprising a dielectric thin film that is formed using a coating solution that is formed by dissolving a precursor for a first substance selected from among aluminum nitride, aluminum chloride and aluminum acetate and a precursor for a second substance selected from among zirconium nitride, zirconium chloride and zirconium acetate into a solvent in which two solvents selected from among acetonitrile, ethylene glycol, 2-methoxy ethanol, ammonia solution, acetic acid and isopropyl alcohol are mixed.

11. The transparent inorganic thin-film transistor according to claim 10, wherein the dielectric thin film is formed by heat treatment at a temperature of 300° C. or below.
